(19) United States
(12) Patent Application Publication
(10) Pub. No.: US 2026/0230091 A1
(43) Pub. Date: Aug. 6, 2026

(54) LOW-DENSITY PARITY-CHECK DECODER AND DECODING METHOD

(71) Applicant: RAYMX Microelectronics Corp., ANHUI PROVINCE (CN)

(72) Inventors: Ying-Hui Zhu, Hefei City (CN); Wei Liu, Jiangsu Province (CN)

(21) Appl. No.: 19/218,981

(22) Filed: May 27, 2025

(30) Foreign Application Priority Data
Feb. 5, 2025 (CN) 202510129258.X

(51) Int. Cl. H03M 13/11; H03M 13/25

(52) U.S. Cl. CPC H03M 13/1108; H03M 13/1111; H03M 13/255

(57) ABSTRACT

A low-density parity-check decoder and a decoding method are provided. In the method, a first decoding algorithm is performed on a received encoded signal. When the first decoding algorithm fails, it is determined to retry the first decoding algorithm based on a degree of codeword error generated in the decoding process. Thus, the first decoding algorithm is again performed after adding perturbation to the codeword. If the first decoding algorithm still fails and does not meet a retry condition, a second decoding algorithm is then performed on the encoded signal. When the second decoding algorithm fails, it is determined to retry the second decoding algorithm based on a degree of codeword error generated in the decoding process. The second decoding algorithm is again performed after the parameters of the algorithm are adjusted.

### CROSS-REFERENCE TO RELATED PATENT APPLICATION

This application claims the benefit of priority to patent application No. 202510129258.X, filed on Feb. 5, 2025, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a low-density parity-check (LDPC) decoding circuit and a method, and more particularly to an LDPC decoder with a retry mechanism and a decoding method.

### BACKGROUND OF THE DISCLOSURE

For ensuring accuracy of a stored data, a conventional error correction code (ECC) is a tool for a decoder to perform a specific error correction algorithm on a data block with error bits. However, the conventional ECC algorithm requires a higher computing resource to achieve a better error correction capability.

When a three-dimensional manufacturing process is available for production of a flash memory with more layers of stacks, a storage density of the flash memory becomes higher and a low-density parity-check (LDPC) code, which is a type of an error correction code, is highly required for an increasing probability of error in the flash memory. Therefore, it is urgent to optimize an LDPC decoding algorithm when 2K-codeword LDPC codes are one-by-one transferred to 4K-codeword LDPC codes.

### SUMMARY OF THE DISCLOSURE

The present disclosure relates to a low-density parity-check (LDPC) decoder and a decoding method that relies on characteristics of the low-density parity-check decoder to optimize a decoding algorithm.

In one of the embodiments, the LDPC decoder includes a decoding core and a control circuit. The control circuit is used to control the decoding core to perform the decoding method.

According to one embodiment of the present disclosure, encoded signal is obtained from a memory, and the LDPC decoder performs a first decoding algorithm on the encoded signal. It is determined whether the decoding process is successful according to a result of the first decoding algorithm. In response to failure of the first decoding algorithm and satisfying a first retry condition relevant to an error level of the codeword that is obtained when the first decoding algorithm is performed, a first retry decoding process is performed.

The first decoding algorithm is a bit-flipping algorithm, and the error level of the codeword corresponds to a relationship between an error bit per codeword and a frame error rate obtained by performing the bit-flipping algorithm. Accordingly, it is determined whether or not to re-perform the bit-flipping algorithm according to the relationship between the error bit per codeword and the frame error rate.

Further, adding the perturbation to the encoded signal is to perform bit flipping on multiple preset bits of the codeword, in which the multiple preset bits are multiple start bits, end bits or random bits of the codeword.

Further, when it is determined that the decoding fails and the first retry condition is not met according to a result of the first decoding algorithm being performed again or for many times, the second decoding algorithm is performed. A complexity of the second decoding algorithm is higher than the complexity of the first decoding algorithm.

Similarly, after the second decoding algorithm is performed, a second retry decoding process is performed when a second retry condition is met. In the second retry decoding process, parameters of the second decoding algorithm are adjusted and then the second decoding algorithm with the adjusted parameters is re-performed.

Further, the second decoding algorithm can be a MinSum algorithm, it is determined whether or not to re-perform the MinSum algorithm according to a relationship between an error bit per codeword and a frame error rate calculated by the MinSum algorithm.

Further, when the low-density parity-check decoder fails to complete decoding by re-performing the second decoding algorithm and the second retry condition is not met, a soft decision decoding algorithm is performed.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram illustrating a framework of an LDPC decoder that operates a decoding method according to one embodiment of the present disclosure;

FIG. 2 is a flowchart illustrating a process of performing a first decoding algorithm in the decoding method according to one embodiment of the present disclosure;

FIG. 3 is a schematic diagram depicting a waterfall chart that is used to determine whether the first decoding algorithm is re-initiated according to one embodiment of the present disclosure;

FIG. 4 is a flowchart illustrating a process of performing a second decoding algorithm in the decoding method according to one further embodiment of the present disclosure; and

FIG. 5 is a schematic diagram depicting another waterfall chart that is used to determine whether the retry second decoding algorithm is re-initiated according another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

The present disclosure relates to a low-density parity-check (LDPC) decoder and a decoding method. The decoding method relates to improvement of a decoding process using LDPC. One of the objectives of the LDPC decoder and the decoding method is to improve overall error correction performance of the LDPC decoder. The LDPC decoder is widely used in communication systems and storage devices.

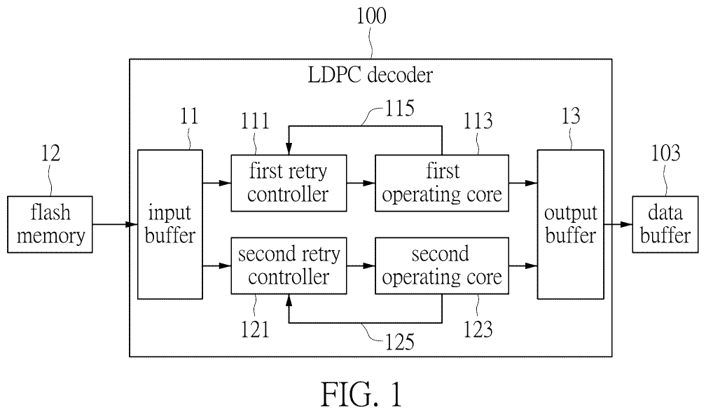

A framework of a LDPC decoder 100 and the decoding method to be operated under the framework can be referred to in a schematic diagram shown in FIG. 1. The LDPC decoder 100 can perform both hard decoding and a soft decoding on signals. The decoding method of the present disclosure uses a high-performance hard decoding method that receives encoded signal (e.g., obtains the encoded signal from a flash memory 12) and also obtains codeword (i.e., n-bit codeword) that is generated when the signal is encoded at the same time. When a decoding algorithm is performed, error correction is performed on the codeword and it is determined whether a result of decoding meets an objective of correction check based on the codeword. The decoding process is successful if the objective is met.

The LDPC decoder 100 includes an input buffer 11, an output buffer 13 and a decoding core that is used to perform the decoding algorithm. The decoding core can include a first operating core 113 and a second operating core 123. The first operating core 113 and the second operating core 123 respectively provide a first decoding algorithm and a second decoding algorithm. The LDPC decoder 100 also includes a control circuit that is coupled to the decoding core. The control circuit is used to control the first operating core 113 and the second operating core 123 for retrying the decoding operation.

When the decoding method is performed, the LDPC decoder 100 obtains the encoded signal from a flash memory 12. The encoded signal is firstly buffered to the input buffer 21, and the LDPC decoder 100 performs at least two decoding algorithms that can be implemented by hardware or through collaboration of hardware and software. The at least two decoding algorithms can be divided into the first decoding algorithm and the second decoding algorithm. Under a requirement of efficiency, the LDPC decoder 100 performs the decoding algorithm by circuits. The decoding method performs the decoding algorithm for at least one time based on various retry criteria.

In one of the embodiments of the present disclosure, a control circuit that is configured to control hardware components of the LDPC decoder is added before the decoding core (e.g., the first operating core 113 and the second operating core 123) that is used to perform the first decoding algorithm and the second decoding algorithm. The control circuit can also be divided into a first retry controller 111 and a second retry controller 121 according to one of the embodiments of the present disclosure. The control circuit can drive the LDPC decoder to enter a retry process automatically. The retry mechanism is exemplarily driven by hardware of the LDPC decoder without intervention of any software or flash memory, so that time cost and computing power used to execute the software can be effectively saved. In an actual operation, a soft decoding method can be a backup after the hard decoding method fails according to one further embodiment.

As the diagram shows, the LDPC decoder 100 uses the first retry controller 111 to control the first operating core 113 to perform the first decoding algorithm. If a first retry condition with respect to the first decoding algorithm is met in the decoding process, a first retry decoding process 115 indicates that the first decoding algorithm is performed in second or more times. If it is determined that the decoding process is successful by checking the codeword, the signal being decoded is transmitted to the output buffer 13 and then outputted to a data buffer 103 of a storage control circuit. According to certain embodiments, it is determined that the decoding process is unsuccessful after the first retry decoding process 115 with respect to the first decoding algorithm, the second decoding algorithm is then performed. For example, the second decoding algorithm is performed when the first decoding algorithm fails at least two times. In one of the embodiments of the present disclosure, a complexity of the second decoding algorithm is higher than the complexity of the first decoding algorithm.

In one further embodiment of the present disclosure, the LDPC decoder 100 uses a second retry controller 121 to control the second operating core 123 to perform the second decoding algorithm on the encoded signal. Similarly, if a second retry condition relating to an error level of the codeword generated in the decoding process with respect to the second decoding algorithm is met, as a second retry decoding process 125 shows that the second decoding algorithm with the parameters being adjusted is performed for a second time or more times. If the decoding process is successful, the decoded signal is transmitted to the output buffer 13 and then outputted to the data buffer 103 of the storage control circuit. In one instance, when the LDPC decoder 100 still fails to complete hard decoding by re-performing the second decoding algorithm and the second retry condition is not met, a soft decision decoding algorithm is performed instead.

In should be noted that, in certain embodiments of the present disclosure, the LDPC decoder 100 operates at least two algorithms, for example, that include a bit-flipping algorithm (BFA) and a MinSum algorithm. An automatic condition determination process is provided in the decoding method of the present disclosure for determining whether the corresponding retry condition (i.e., the first retry condition or the second retry condition) is met after the first decoding algorithm or the second decoding algorithm is performed. In an aspect, the determination of the first retry condition or the second retry condition relies on an error level of the codeword that is generated in the decoding process. If one of the retry criteria is met, perturbation can automatically be added to the corresponding decoding algorithm for self-adjustment or parameters of the LDPC decoder are adjusted in order to re-perform decoding. It should be noted that the perturbation configured to be added to the decoding algorithm is such as incorporating errors (e.g., modifying values of part of bits of the codeword) to the decoding algorithm. Because of statistical characteristics of the LDPC decoder 100, based on certain experiments in an instance where a quantity of error bits is not very high, the perturbation can be properly added to the encoded signal being inputted to the decoding algorithm or the parameters of the LDPC decoder can be properly adjusted so as to have the possibility to correct errors of the codeword that cannot be corrected originally.

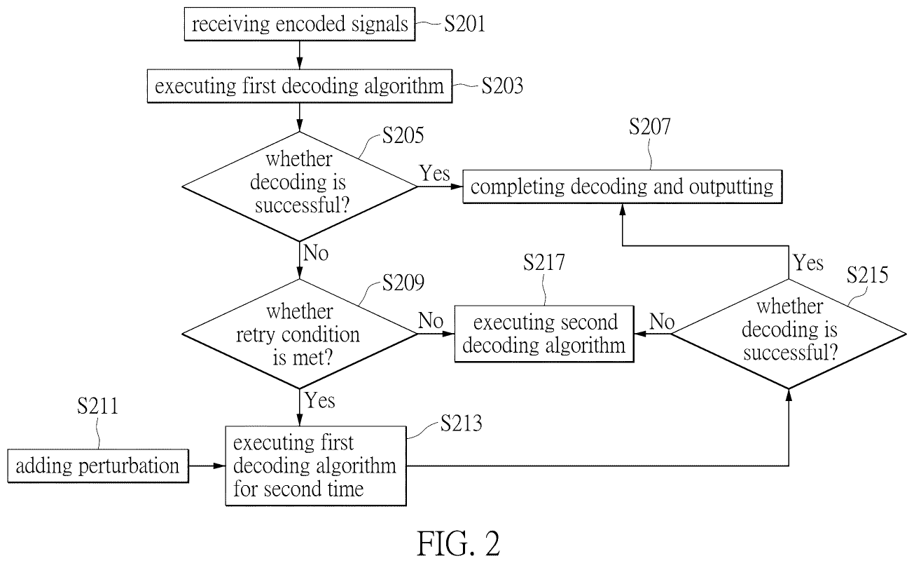

Under the framework of the storage control circuit and the LDPC decoder that can operate at least two decoding algorithms, reference is made to FIG. 2, which is a flowchart illustrating the first decoding algorithm in the decoding method according to one embodiment of the present disclosure.

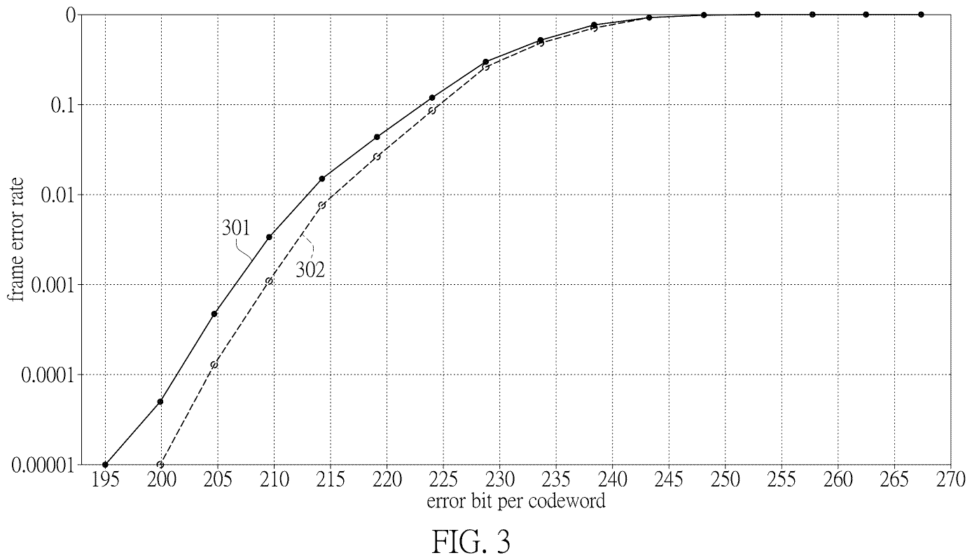

The LDPC decoder firstly reads an encoded signal from a flash memory (step S201), and uses a first operating core to perform a first decoding algorithm (step S203). It is determined whether the decoding process is successful according to information provided from the codeword that is used for error correction in a result when performing the first decoding algorithm (step S205). If it is confirmed that the decoding process is successful (represented as “yes”), the decoded signal is outputted after the decoding process is completed (step S207). Otherwise, if the first decoding algorithm fails to decode the signal (represented as “no”), it is next determined whether the first retry condition is met (step S209). Reference is made to FIG. 3, which is a waterfall chart that denotes the first retry condition with respect to the retry first decoding algorithm according to one embodiment of the present disclosure.

In the step S209, when the first decoding algorithm fails to decode the signal and, in the instance, the first retry condition is not met either (represented as “no”), the second decoding algorithm is next performed according to one embodiment of the present disclosure (step S217). If the first retry condition with respect to the first decoding algorithm is met in the instance (represented as “yes”), the first decoding process is re-performed. In the meantime, in the first retry decoding process, perturbation is added to the codeword of the first decoding algorithm or the parameters of the LDPC decoder in the first decoding algorithm are adjusted (step S211), so that the first decoding algorithm is re-performed (step S213) and whether the decoding process is successful is determined again (step S215).

When the first decoding algorithm is performed for a second time, the perturbation such as few error bits can be added to the first decoding algorithm for retrying decoding successfully since the perturbation allows the decoding algorithm to have a certain probability of successfully decoding. Adding the perturbation to the encoded signal is to perform bit flipping on multiple preset bits of the codeword, in which the multiple preset bits can be multiple start bits, end bits or random bits of the codeword. Thus, in one of the embodiments of the present disclosure, the first decoding algorithm can be a bit-flipping algorithm that is performed to form the perturbation applied to the decoding algorithms by flipping the bits (i.e., bit 0 flipped to bit 1 or bit 1 flipped to bit 0) such as start bits, end bits or other random bits of the codeword. For example, the first 10 bits, last 10 bits or any 10 bits of the codeword in the first decoding algorithm can be taken as being flipped.

In the decoding method, according to one of the embodiments of the present disclosure, the first decoding algorithm with the perturbation is required to be re-performed at least once for determining whether the decoding process is completed. Further, it is also required to repeatedly confirm whether the first retry condition is met after the decoding fails. The first decoding algorithm with the perturbation is then re-performed when the first retry condition is met.

In the above process, if the decoding fails and the first retry condition is not met either, the second decoding algorithm is then performed (step S217). If it is confirmed that the decoding process is successful, the decoded signal is outputted after the decoding process is completed (step S207).

According one embodiment of the present disclosure, the first decoding algorithm can be the bit-flipping algorithm used to achieve decoding correction for a first time. In the bit-flipping algorithm, with 4K-byte LDPC codes as an example, a syndrome of the codeword retrieved from the LDPC decoder is firstly calculated, and bit values of the codeword are obtained. The bit values are confirmed to be compared with a preset threshold so as to determine whether the bit values of the codeword are required to be flipped, e.g., the bit 0 to be flipped to bit 1 or the bit 1 to be flipped to bit 0. Next, the syndrome of the codeword with the flipped bits is re-calculated so as to determine whether the codeword with the bits to be flipped within a specific number of recursions is a correct codeword. This operation will be stopped if it is confirmed that the codeword is correct.

In the step S209 of FIG. 2 for determining whether the first retry condition is met, the first decoding algorithm is such as the bit-flipping algorithm, and the error level of the codeword corresponds to a relationship between the error bit per codeword and the frame error rate obtained by the bit-flipping algorithm, thereby determining whether or not the bit-flipping algorithm is required to be re-performed. When the first decoding algorithm such as the bit-flipping algorithm fails to successfully decode the signal, referring to an exemplary example shown in FIG. 3, which is a schematic diagram of a waterfall chart depicting a relationship between the error bit per codeword and the frame error rate and used to determine whether the first decoding algorithm is required to be re-performed according to one embodiment of the present disclosure.

A vertical axis of the waterfall chart shown in FIG. 3 denotes the frame error rate and a horizontal axis of the waterfall chart denotes the error bit per codeword. The waterfall chart includes two curves respectively having a de-activation retry curve 301 and an activation retry curve 302. A trend illustrated by both the de-activation retry curve 301 and the activation retry curve 302 indicates that the frame error rate is higher if the error bit per codeword is bigger, and the frame error rate approaches “1” if the error bit per codeword reaches a certain quantity, e.g., 250. Further, the waterfall chart also indicates that the closer to the right side of the chart, the stronger decoding ability the decoder has. That means that the decoder has a better retry decoding ability if the error bit per codeword is more and the frame error rate is higher.

According to the exemplary example shown in the chart of FIG. 3, the de-activation retry curve 301 and the activation retry curve 302 are referred to for defining a condition for determining whether or not to re-perform the bit-flipping algorithm. When a LDPC decoder performs a bit-flipping algorithm, an error bit per codeword can be determined and a corresponding frame error rate can be calculated according to a codeword retrieved from the encoded signal. Referring to the de-activation retry curve 301 and the activation retry curve 302, if a calculated frame error rate corresponding to the error bit per codeword matches the de-activation retry curve 301, it shows that the calculated frame error rate does not meet the condition for re-performing the bit-flipping algorithm. If the calculated frame error rate corresponding to the error bit per codeword matches the activation retry curve 302, the condition for re-performing the bit-flipping algorithm is met.

Referring to the step S209 of FIG. 2, if the first retry condition is not met or the decoding process fails after the first decoding algorithm is performed for two or more times, the process will proceed to the step S217 of FIG. 2 for performing the second decoding algorithm.

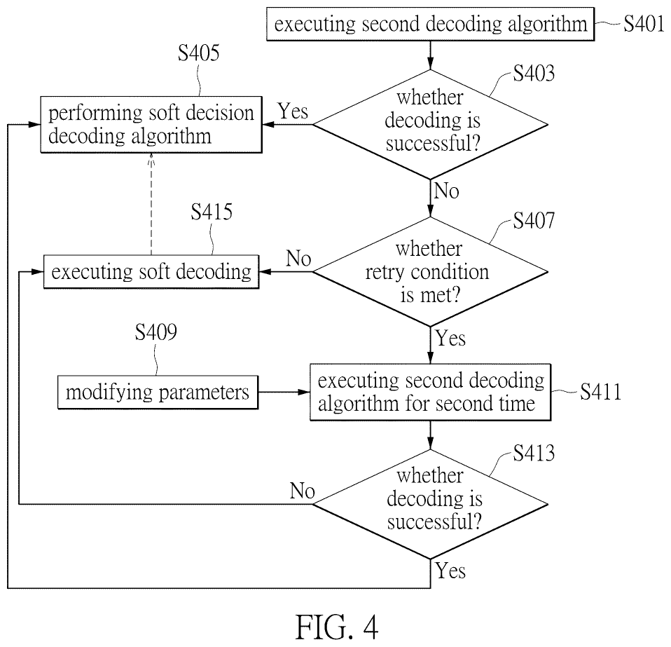

Reference is next made to FIG. 4, which is a flowchart illustrating the second decoding algorithm in the decoding method according to one embodiment of the present disclosure. For the storage control circuit described in the above embodiments, the LDPC decoder operates at least two decoding algorithms. The second decoding algorithm is such as a MinSum algorithm.

After the LDPC decoder performs the second decoding algorithm (step S401), it is determined whether a decoding process is successful according to a codeword generated in the decoding process (step S403). If the decoding process is successful (represented as “yes”), the decoding process is then completed and the decoded signal is outputted (step S405). Otherwise, if the decoding process fails (represented as “no”), it is determined whether a second retry condition is met according to an error level of the codeword generated in the decoding process (step S407).

According to certain embodiments of the present disclosure, the second decoding algorithm is such as the MinSum algorithm using hard decision that relies on a relationship between the error bit per codeword and the frame error rate that is generated by performing the MinSum algorithm to determine whether or not to re-perform the MinSum algorithm. The second retry condition that is used to determine whether or not to re-perform the MinSum algorithm is corresponding to a relationship between the error bit per codeword and the frame error rate generated by the MinSum algorithm. Reference is made to FIG. 6, which is a schematic diagram illustrating another waterfall chart that is referred to for determining whether or not to re-perform the retry second decoding algorithm according to one embodiment of the present disclosure.

In the step S407 of FIG. 4, when the decoding process still fails, it is determined that the second retry condition cannot be met (represented as “no”), and a soft decision decoding algorithm can be performed according to a predetermined backup approach (step S415) in order to complete the decoding process (step S405). Otherwise, when the decoding process fails but the second retry condition is met (represented as “yes”), the second decoding algorithm is performed for a second time (step S411). When the second decoding algorithm is performed for the two or more times, the parameters for the algorithm are configured to be modified, e.g., the parameters in Equation 1 (step S409). Table 1 shows an exemplary example of the parameters to be modified for the MinSum algorithm. After that, it is continuously determined whether the decoding process is successful according to the codeword obtained from every result of decoding when the second decoding algorithm is re-performed for a second time or more times (step S413). In the above decoding process, even if the decoding process fails for many times, the parameters for the second decoding algorithm can continuously be modified for retrying the decoding process if the second retry condition is still met.

If the decoding process is successful after retrying the decoding process for the second time or more times (represented as “yes”), a result of decoding is outputted for completing the decoding process (step S405) and this process is terminated; otherwise, if the decoding process fails after retrying the decoding process for the second time or more times (represented as “no”), and the second retry condition cannot be met, the process proceeds the predetermined backup approach, i.e., the soft decoding (step S415). It should be noted that the software decision decoding algorithm can be a MinSum algorithm using soft decision.

Taking the MinSum algorithm as an example, the MinSum algorithm only determines a minimum value in a check node operation, so that the LDPC decoding algorithm can be simplified. As shown in Equation 1, “m” represents a check node number in the MinSum algorithm, “n” represents a variable node number, “rm-n” represents information that a number “m” check node provides a number “n” variable node; and a variable “a” is a scaling parameter, “q_{n′→m}” represents information that a number “n′” variable node of codeword provides to the number “m” check node, such as a log-likelihood ratio (LLR). Further, a sign function “sign( )” returns 0, 1 or −1 based on a numerical value “q_{n′→m}” in the sign function that can be 0, a positive value or a negative value. An outcome of the sign function “sign(q)” can be divided into two parameters such as “an” and “ap” that can be selected based on a computation power of the decoder. Still further, “L(xₙ)” represents a value of the variable node to the check node. Thus, when the second decoding algorithm is performed twice or more times, the decoding process is retried by modifying the two parameters “an” and “ap”, which is to attempt decoding based on a certain probability of success.

$${r}_{m \to n} = α ( \prod sign ( {q}_{{n}^{′} \to m} ) ) min ( \vert {q}_{{n}^{′} \to m} \vert ) ; \qquad Equation 1$$

$${q}_{n \to m} = {y}_{n} + \sum {r}_{{m}^{′} \to n} ( {x}_{n} ) ;$$

$$L ( {x}_{n} ) = {y}_{n} + \sum {r}_{m \to n} ( {x}_{n} ) .$$

Table 1 shows an exemplary example of parameters to be modified for the MinSum algorithm, in which the parameters are modified twice. The decoding process is configured to repeatedly perform the MinSum algorithm with the parameters that are step-by-step adjusted for achieving decoding.

TABLE 1

| Parameters | αn | αp |
|---|---|---|
| first decoding parameters | 0.6875 | 0.8125 |
| Second decoding parameters | 0.625 | 0.75 |

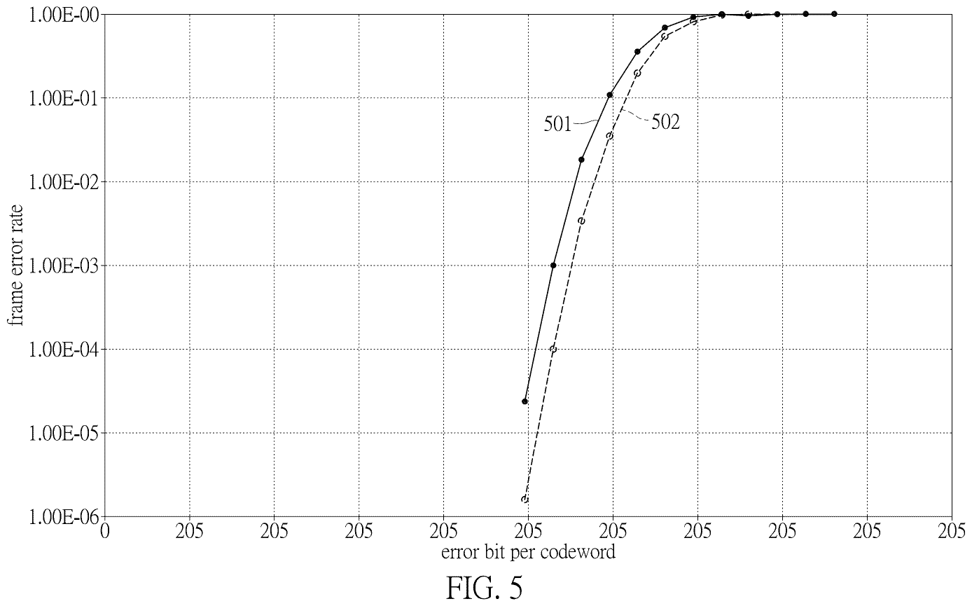

Reference is made to FIG. 5, which is a schematic diagram depicting a waterfall chart that is referred to for determining whether the second decoding algorithm (e.g., the MinSum algorithm) is re-performed according to one embodiment of the present disclosure. The waterfall chart depicts a relationship between an error bit per codeword and a frame error rate. The waterfall chart includes a de-activation retry curve 501 and an activation retry curve 502, and both have a same trend indicating that the bigger the error bit per codeword, and the higher the frame error rate is. When the error bit per codeword reaches a specific quantity, e.g., 350, the frame error rate approaches 1.

Thus, the above-described retry decoding method can define a condition to determine whether to re-perform the MinSum algorithm by the de-activation retry curve 501 and the activation retry curve 502. When the LDPC decoder performs the MinSum algorithm, the codeword retrieved from the decoded signal is referred to for determining the error bit per codeword and calculating a corresponding frame error rate. Referring to the waterfall chart shown in FIG. 5, the condition for determining whether to re-perform the MinSum algorithm is not met if the calculated frame error rate corresponding to the error bit per codeword matches the de-activation retry curve 501; or, the condition for determining whether to re-perform the MinSum algorithm is met if the calculated frame error rate corresponding to the error bit per codeword matches the activation retry curve 502.

Furthermore, referring to the process shown in FIG. 4, the soft decision decoding algorithm will be performed (FIG. 4, step S415) if the decoding process fails after the second decoding algorithm is performed for the first, second or more times, and the second retry condition is not met either.

In conclusion, according to the above embodiments relating to the decoder low-density parity-check (LDPC) decoder and the decoding method, the decoding method applies characteristics of an LDPC decoding algorithm to enhance hard decoding performance of error correction of the LDPC decoder based on an original LDPC decoding algorithm. Therefore, an error-floor of LDPC can be reduced, and the performance of a waterfall region before a sudden drop when reaching a specific signal-to-noise ratio can also be enhanced. Further, the decoding method provides a retry decoding mechanism for effectively improving a success rate of LDPC decoding and reducing impact of the retry decoding mechanism on the performance of the LDPC decoder through a proper retry determination.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A decoding method, which is performed in a low-density parity-check decoder, comprising:
receiving an encoded signal;
performing a first decoding algorithm on the encoded signal;
in response to the first decoding algorithm failing to decode and satisfying a first retry condition related to an error level of codeword generated by the first decoding algorithm, determining to perform a first retry decoding process;
wherein the first retry decoding process comprises:
performing at least one of adding perturbation to the encoded signal or adjusting parameters of the first decoding algorithm; and
re-performing the first decoding algorithm.

2. The decoding method, according to claim 1, wherein a second decoding algorithm is performed on the encoded signal when the first decoding algorithm fails in response to a result of the first decoding algorithm being performed at least two times.

3. The decoding method according to claim 1, wherein, in response to the first decoding algorithm failing and not satisfying the first retry condition related to the error level of codeword generated by the first decoding algorithm, performing a second decoding algorithm, wherein a complexity of the second decoding algorithm is higher than the complexity of the first decoding algorithm.

4. The decoding method according to claim 3, wherein the first decoding algorithm is a bit-flipping algorithm and the second decoding algorithm is a MinSum algorithm.

5. The decoding method according to claim 3, wherein, in response to satisfying a second retry condition related to the error level of codeword generated by the second decoding algorithm, determining to perform a second retry decoding process;
wherein the second retry decoding process comprises:
adjusting parameters of the second decoding algorithm; and
re-performing the second decoding algorithm.

6. The decoding method according to claim 2, wherein, in response to the second decoding algorithm failing to decode and not satisfying the second retry condition related to the error level of codeword generated by the second decoding algorithm, performing a soft decision decoding algorithm.

7. The decoding method according to claim 6, wherein the first decoding algorithm is a bit-flipping algorithm, the second decoding algorithm is a MinSum algorithm using hard decision, and the soft decision decoding algorithm is a MinSum algorithm using soft decision.

8. The decoding method according to claim 1, wherein the first decoding algorithm is a bit-flipping algorithm, and the error level of the codeword corresponds to a relationship between an error bit per codeword and a frame error rate obtained by performing the bit-flipping algorithm.

9. The decoding method according to claim 1, wherein the first decoding algorithm is a bit-flipping algorithm, and adding perturbation to the encoded signal is to perform bit flipping on multiple preset bits of the codeword, in which the preset bits are multiple start bits, end bits or random bits.

10. A decoder, comprising:
a decoding core comprising:
a first operating core, configured to perform a first decoding algorithm; and
a second operating core, configured to perform a second decoding algorithm, wherein a complexity of the second decoding algorithm is higher than that of the first decoding algorithm;
and
a control circuit, coupled to the decoding core, configured to control the operating core to perform a decoding method comprising:
obtaining an encoded signal;
performing the first decoding algorithm on the encoded signal;
in response to the first decoding algorithm failing to decode and satisfying a first retry condition related to the error level of codeword generated by the first decoding algorithm, determining to perform a first retry decoding process;
wherein the first retry decoding process comprises:
adding perturbation to the codeword of the first decoding algorithm; and
re-performing the first decoding algorithm with the perturbation.

11. The decoder according to claim 10, wherein the second decoding algorithm is performed on the encoded signal when the first decoding algorithm fails in response to a result of the first decoding algorithm being performed at least two times.

12. The decoder according to claim 11, wherein, in response to the second decoding algorithm failing to decode, the second decoding algorithm with adjusted parameters is re-performed.

13. The decoder according to claim 12, wherein the second decoding algorithm is a MinSum algorithm, and whether to re-perform the MinSum algorithm is determined according to a relationship between an error bit per codeword and a frame error rate that is obtained by performing the MinSum algorithm.

14. The decoder according to claim 11, wherein, when the second decoding algorithm fails to decode, the second decoding algorithm using soft decision is performed.

15. The decoder according to claim 10, wherein the first decoding algorithm is a bit-flipping algorithm, and whether or not to re-perform the bit-flipping algorithm is determined according to a relationship between an error bit per codeword and a frame error rate that is obtained by performing the bit-flipping algorithm.

16. The decoder according to claim 11, wherein, in response to satisfying a second retry condition related to the error level of codeword generated by the second decoding algorithm, the second decoding algorithm with adjusted parameters is re-performed.

17. The decoder according to claim 16, wherein the second decoding algorithm is a MinSum algorithm, and the second retry condition corresponds to a relationship between an error bit per codeword and a frame error rate that is obtained by performing the MinSum algorithm.

18. The decoder according to claim 17, wherein, in response to the second decoding algorithm failing to decode and not satisfying the second retry condition related to the error level of codeword generated by the second decoding algorithm, a soft decision decoding algorithm is performed.

19. The decoder according to claim 18, wherein the first decoding algorithm is a bit-flipping algorithm, the second decoding algorithm is a MinSum algorithm using hard decision, and the soft decision decoding algorithm is a MinSum algorithm using soft decision.
